(19) United States
(12) Patent Application Publication
(10) Pub. No.: US 2021/0276874 A1
(43) Pub. Date: Sep. 9, 2021

(54) METHOD FOR MANUFACTURING GRAPHENE-METAL COMPOSITE WIRE

(71) Applicant: Nankai University, Tianjin (CN)

(72) Inventors: Yongsheng Chen, Tianjin (CN); Tengfei Zhang, Tianjin (CN); Ai Ren, Tianjin (CN)

(21) Appl. No.: 17/261,689

(22) PCT Filed: Jul. 23, 2019
(86) PCT No.: PCT/CN2019/097285

§ 371 Date: Jan. 25, 2021

(30) Foreign Application Priority Data
Jul. 24, 2018 (CN) 201810817130.2

(51) Int. Cl. C01B 32/186; C23C 16/26; C23C 16/56; H01B 1/04

(52) U.S. Cl. CPC C01B 32/186; C23C 16/26; C23C 16/56; H01B 1/04; C01B 2204/24; C01B 2204/20; C01P 2004/03; C01P 2002/82; C01B 2204/22; C01B 2204/26

(57) ABSTRACT

The present disclosure provides a method for manufacturing a graphene-metal composite wire. The method includes: (1) growing graphene on a surface of a metal wire through a chemical vapor deposition process; (2) twisting the wire; (3) pretensioning and pre-straining the wire; (4) cold-drawing the wire; and (5) subjecting the wire to a chemical vapor deposition process, wherein the wire is subjected to steps (2) to (5) successively and cycled n times, wherein f wires obtained in step (1) are used in the first cycle, f wires obtained from previous cycle are used in subsequent cycle, and finally a graphene-metal composite wire with fn strands is obtained, and wherein (a) f is an integer of 2-9; and (b) n is an integer of 6 or more.

### TECHNICAL FIELD

The present disclosure relates to a method for manufacturing a graphene-metal composite wire, and specifically to a method for manufacturing a graphene-metal composite wire that has a multi-strand structure in which graphene is uniformly distributed.

### BACKGROUND

At present, the methods for manufacturing graphene mainly refer to mechanical exfoliation process, redox process, chemical vapor deposition (CVD) process, and the like. However, compared with the first two processes, the chemical vapor deposition process can obtain graphene with high quality and controllable layers through catalysis with a specific metal substrate in the presence of methane, acetylene, or the like as a carbon source. It is worth noting that high-quality graphene may also grow on a polycrystalline metal substrate, and the polycrystalline metal substrate is cheaper than a monocrystalline metal substrate. Therefore, the chemical vapor deposition process is one of the efficient methods expected to be used for large-scale production of high-quality graphene.

Because graphene has a series of excellent properties, graphene-based composite materials can highly pertinently and significantly improve the defects and disadvantages of the materials. At present, when manufacturing a graphene-metal composite material, introduced graphene is usually obtained by mechanically exfoliating graphite or reducing oxidized graphene. Such a graphene material is physically or chemically combined with a metal powder or a metal precursor and then further processed to obtain a graphene-metal composite material, but it is difficult to completely solve the problem of dispersion uniformity and interface phase separation of various components.

Manufacturing the graphene-metal composite material by in-situ growth of graphene on the surface of metal particles using the CVD process is an efficient means expected to solve the dispersion problem and ensure interfacial bonding. However, the greatest advantage of the metal substrate lies in production of a large-area graphene film rather than small-size graphene. Further, the metal particles are also very easy to sinter at a high temperature and graphene cannot be uniformly formed on the surface of the particles. At present, such CVD process neither guarantees uniform distribution of graphene on zero-dimensional or three-dimensional metal substrates, nor guarantees interfacial interaction between graphene and metal.

In view of the above, the disclosure provides a method for manufacturing a graphene-metal composite wire in order to solve some existing problems.

### SUMMARY

According to an aspect of the present disclosure, a method for manufacturing a graphene-metal composite wire is provided. The method includes: (1) growing graphene on a surface of a metal wire through a chemical vapor deposition process; (2) twisting the wire; (3) pre-tensioning and pre-straining the wire; (4) cold-drawing the wire; and (5) subjecting the wire to a chemical vapor deposition process, wherein the wire is subjected to steps (2) to (5) successively and cycled n times, wherein f wires obtained in step (1) are used in the first cycle, f wires obtained from previous cycle are used in subsequent cycle, and finally a graphene-metal composite wire with strands is obtained, and wherein (a) f is an integer of 2-9; and (b) n is an integer of 6 or more. According to another embodiment, the method includes: step (3′) between step (3) and step (4): subjecting the wire to a chemical vapor deposition process so that graphene grows on the surface thereof.

According to an embodiment, the metal wire is washed before step (1), and the washing includes washing the metal wire with one or more solvents selected from the group consisting of deionized water, ethanol, acetone, isopropanol, and trichloromethane, and repeating the washing 2-3 times. According to another embodiment, the chemical vapor deposition process in step (1) is an atmospheric pressure chemical vapor deposition process or a low-pressure chemical vapor deposition process at a pressure of 1-300 Pa, in which a carrier gas is selected from the group consisting of argon, helium, hydrogen, and any combination thereof; a carbon source is a gaseous carbon source or a liquid carbon source, the gaseous carbon source is selected from the group consisting of methane, ethane, ethylene, and any combination thereof, and the liquid carbon source is selected from the group consisting of methanol, ethanol, methylbenzene, and any combination thereof.

According to an embodiment, the chemical vapor deposition process in step (1) comprises heat-treating the metal wire by heating the metal wire to a temperature of 800-1100° C. and maintaining for 30-100 minutes; heating the metal wire to a growth temperature that is in a range of 800-1100° C. and equal to or higher than the heat treatment temperature, and contacting the metal wire with a carrier gas carrying a carbon source, so that graphene grows on the surface of the metal wire for 5-60 minutes, wherein the carrier gas has a flow rate of 1-500 ml/min. According to another embodiment, the chemical vapor deposition process used in step (5) and the chemical vapor deposition process used in the optional step (3′) are the same as the chemical vapor deposition process in step (1).

According to an embodiment, the twisting in step (2) is carried out in an atmosphere of air, argon or helium, and a twisting degree is 5-40 T/cm. According to another embodiment, step (3) comprises heat-treating the wire at 600-1100° C. for 30-60 minutes so that the wire becomes slack; subjecting the wire to a pre-tensioning operation immediately after the heat treatment, then cooling the wire to below 200° C. for a pre-straining operation. According to another embodiment, step (3) is repeated 3-8 times in a single cycle so that an elongation of the wire is 10-30%.

According to an embodiment, step (4) comprises subjecting the wire obtained in step (3) or (3′) to cold drawing with a cold drawing die at atmospheric pressure and room temperature 1-30 times, wherein the wire is elongated by 2-5% during each cold drawing. According to another embodiment, a diameter of the wire finally obtained in step (4) is the same as initial diameter of the metal wire in step (1).

According to an embodiment, the metal wire is a copper wire or a nickel wire. According to another embodiment, the metal wire is a red copper wire with a purity of 95-99.999% and a diameter of 0.05-0.5 mm.

### BRIEF DESCRIPTION OF THE DRAWINGS

The accompanying drawings are only used to illustrate one or more embodiments of the present disclosure together with the description, but are not intended to limit the scope of the present disclosure.

FIG. 1 is a schematic structural diagram of a graphene-metal composite wire with fn strands;

FIG. 2 is a Raman spectrum of graphene according to Example 1;

FIG. 3 is a SEM image of a wire obtained after twisting according to Example 2;

FIG. 4 is a SEM image of the graphene-copper composite wire obtained after cold drawing with a die according to Example 3;

FIG. 5 is an optical image of oxidation resistance of the graphene-copper composite wire according to Example 4; and

FIG. 6 shows comparison of tensile strength of the graphene-copper composite wire according to Example 7.

### DETAILED DESCRIPTION

In order to better understand the contents of the present disclosure, several specific embodiments are provided below. Those skilled in the art will be able to modify the embodiments according to actual situations, and may also combine the technical features of different embodiments.

In an embodiment, a method for manufacturing a graphene-metal composite wire is provided. The method includes: (1) growing graphene on a surface of a metal wire through a chemical vapor deposition process; (2) twisting the wire; (3) pretensioning and pre-straining the wire; (4) cold-drawing the wire; and (5) subjecting the wire to a chemical vapor deposition process, wherein the wire is subjected to steps (2) to (5) successively and cycled n times, wherein f wires obtained in step (1) are used in the first cycle, f wires obtained from previous cycle are used in subsequent cycle, and finally a graphene-metal composite wire with fn strands is obtained, and wherein (a) f is an integer of 2-9; and (b) n is an integer of 6 or more. In another embodiment, according to the above step (1), a graphene-coated metal wire can be obtained through in-situ growth of graphene with high coverage, high quality, and controllable layers on the metal surface. In still another embodiment, according to the above step (1), a graphene-coated composite copper wire can be obtained with a commercial red copper wire as a starting material.

The high coverage herein means that the coverage of graphene on the metal surface is higher than 99%, preferably higher than 99.5%, 99.6%, 99.7%, 99.8%, or 99.9%. The number of graphene layers on the metal surface herein is controlled to 1-10, e.g., 1, 2, 3, 4, 5, 6, 7, 8, 9, or 10.

In an embodiment, the chemical vapor deposition process in step (1) is an atmospheric pressure chemical vapor deposition process. In another embodiment, the chemical vapor deposition process in step (1) is a low-pressure chemical vapor deposition process, wherein the pressure is 1-300 Pa, e.g., 50, 100, 150, 200, 250 Pa.

In still another embodiment, in step (1), the carrier gas is selected from the group consisting of argon, helium, hydrogen, and any combination thereof, e.g., the carrier gas is a combined gas of argon and hydrogen. In a further embodiment, in step (1), the carbon source is a gaseous carbon source or a liquid carbon source, the gaseous carbon source is selected from the group consisting of methane, ethane, ethylene, and any combination thereof, and the liquid carbon source is selected from the group consisting of methanol, ethanol, methylbenzene, and any combination thereof. Preferably, the gaseous carbon source, e.g., methane or ethane, is used.

In an embodiment, the chemical vapor deposition process in step (1) comprises heat-treating the metal wire by heating the metal wire to a temperature of 800-1100° C. and maintaining for 30-100 minutes; heating the metal wire to a growth temperature that is in a range of 800-1100° C. and equal to or higher than the heat treatment temperature, and contacting the metal wire with a carrier gas carrying a carbon source, so that graphene grows on the surface of the metal wire for 5-60 minutes, wherein the carrier gas has a flow rate of 1-500 ml/min. In another embodiment, the heat treatment temperature is 800, 850, 900, 950, 1000, or 1050° C. In still another embodiment, the growth temperature is 850, 900, 950, 1000, 1050, or 1100° C. In an embodiment, the growth duration of graphene is 5-60 minutes, preferably 10-40 minutes, e.g., 10, 15, 20, 25, 30, 35, or 40 minutes.

In an embodiment, the metal wire is washed before step (1), and the washing includes washing the metal wire with one or more solvents selected from the group consisting of deionized water, ethanol, acetone, isopropanol, and trichloromethane, and repeating the washing 2-3 times. In another embodiment, the metal wire is washed with deionized water, ethanol, and acetone successively, and the washing is repeated 2-3 times.

In an embodiment, the twisting in step (2) is carried out in an atmosphere of air, argon, or helium, and a twisting degree is 5-40 T/cm, e.g., 5, 10, 15, 16, 20, 25, 30, 35, or 40 T/cm. In another embodiment, in step (2), 2-9 graphene-coated wires may be twisted, or 2-9 wires processed in previous cycle may be twisted. for example, 2, 3, 4, 5, 6, 7, 8, or 9 wires are twisted. After twisting, a part of graphene may be wrapped by other surrounding metal wires, and after steps (3) and (4) described herein, graphene may be distributed inside the composite wire.

In an embodiment, step (3) comprises heat-treating the wire at 600-1100° C. for 30-60 minutes so that the wire becomes slack; subjecting the wire to a pre-tensioning operation immediately after the heat treatment, then cooling the wire to below 200° C. for a pre-straining operation. In another embodiment, the heat treatment temperature in step (3) is 600-1100° C., 650-1050° C., 700-1000° C., 750-950° C., or 800-900° C., and the heat treatment duration is 30-60 minutes, 35-55 minutes, or 40-50 minutes. In still another embodiment, step (3) may be repeated 3-8 times, e.g., 3-5 times, so that an elongation of the wire is 10-30%, e.g., 10, 15, 18, 20, 25, or 30%. In another embodiment, when step (3) is repeated, the same or different heat treatment temperatures may be employed, and the same or different heat treatment durations may be employed. A stress generated by twisting and stretching can be eliminated in step (3) of the present disclosure, to achieve good interfacial contact between metal wires and between the metal wire and graphene, therefore the entire structure is densified, i.e., achieving the structure densification.

In an embodiment, an optional step (3′) is arranged between step (3) and step (4) as required, which comprises: subjecting a wire obtained in previous step to a chemical vapor deposition process so that graphene grows on the surface thereof. In another embodiment, the chemical vapor deposition process used in step (3′) is the same as the chemical vapor deposition process in step (1). In still another embodiment, the chemical vapor deposition process used in step (3′) is different from the chemical vapor deposition process in step (1). In an embodiment, when cycle steps (2)-(5) are repeated, step (3′) may be optionally implemented, i.e., step (3′) may be implemented in each cycle, or step (3′) may not be implemented in each cycle, or step (3′) may also be implemented as required.

In an embodiment, step (4) comprises subjecting the wire obtained in step (3) or (3′) to cold drawing with a cold drawing die at atmospheric pressure and temperature 1-30 times, wherein the wire is elongated by 2-5% during each cold drawing. In another embodiment, the diameter of the wire finally obtained in step (4) is the same as the initial diameter of the metal wire in step (1), i.e., obtaining a graphene-metal composite wire with the diameter identical to the initial diameter of the metal wire, with an increased length and with graphene uniformly distributed inside. In still another embodiment, the cold drawing die is a diamond high-precision drawing die with a round hole, and a drawing lubricant may or may not be added during the drawing.

In an embodiment, the chemical vapor deposition process used in step (5) is the same as the chemical vapor deposition process in step (1). In another embodiment, the chemical vapor deposition process used in step (5) is different from the chemical vapor deposition process in step (1).

In an embodiment, the wire may be subjected to steps (2) to (5) successively and cycled n times, where n is an integer of 6 or more, for example, but not limited to, 6, 7, 8, 9, 10, 11, 12, 13, 14, 15, 16, 17, 18, 19 or 20. In another embodiment, f wires obtained in step (1) are used in a first cycle, f wires obtained from previous cycle are used in each subsequent cycle, and finally a graphene-metal composite wire with to fn strands is obtained, where f is an integer of 2-9, e.g., 2, 3, 4, 5, 6, 7, 8, or 9.

In an embodiment, the metal wire is a copper wire or a nickel wire. In another embodiment, the metal wire is a red copper wire with a purity of 95-99.999% and a diameter of 0.05-0.5 mm, preferably a commercial red copper wire. In such embodiment, copper is used as a substrate. Since copper hardly forms a solid solution with carbon, copper mainly plays a catalytic role in the growth of graphene. However, once graphene covers the surface of the copper substrate, the catalytic effect of copper covered by graphene is largely suppressed, thereby hindering the further deposition of carbon atoms and the increase of the number of graphene layers. Therefore, the method of the present disclosure can very efficiently obtain a graphene film with a few of layers or even a single layer by adjusting the process parameters.

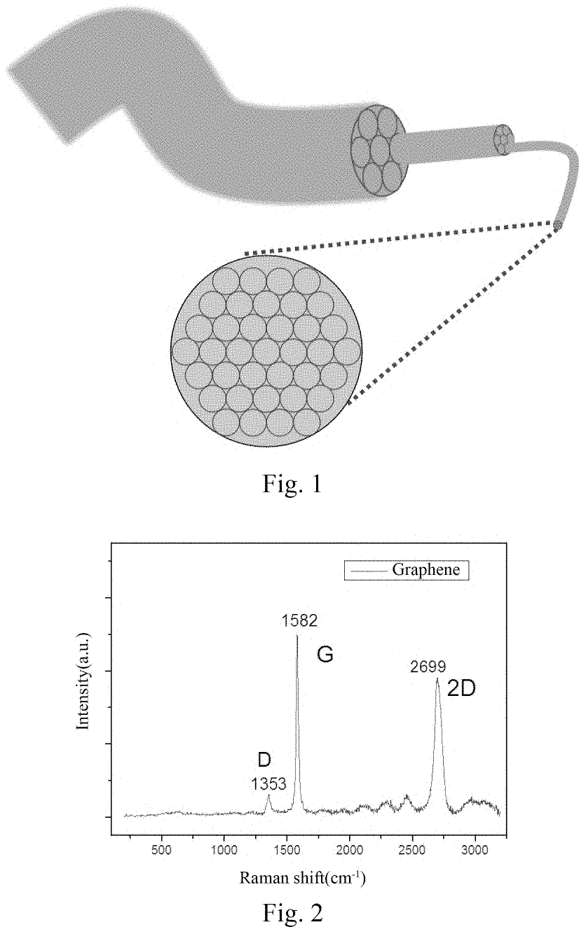

The method according to present disclosure comprises in-situ growth of graphene on the metal wire; then successively performing twisting, pre-tensioning and pre-straining (densifying), and cold drawing with a die; performing a plurality of cycles consisting of the above steps, thereby finally obtaining a composite wire with graphene uniformly distributed inside and with good interfacial interaction between graphene and the metal substrate from a microscopic perspective (see FIG. 1 for schematic structural diagram thereof). The wire has excellent electrical and thermal conducting properties, efficiently improved mechanical strength, and excellent oxidation resistance and corrosion resistance. In addition, continuous production can be realized using the method of the present disclosure.

Further, according to the present disclosure, there is good interfacial interaction between metal crystal grains and graphene by in-situ growth of graphene, and several processing technologies are combined and cycled many times, thereby effectively solving the problem that graphene and metal materials are dispersed in the bulk phase, and overcoming the defect that metal wires (e.g., copper wires) cannot be used to prepare large-area and high-quality graphene. Further, simple and continuous operations are used in the method of the present disclosure, thereby facilitating the implementation of large-scale production.

### EXAMPLES

Embodiments of the present disclosure will be further described below by providing examples. However, those skilled in the art will understand that the provided examples are only used to illustrate the present disclosure clearly, and are not intended to limit the scope of the present disclosure in any way.

### Example 1

(1) A commercial copper wire with a diameter of 0.1 mm and a purity of 99% was washed with deionized water, ethanol, and acetone successively, and the washing was repeated 3 times. An atmospheric pressure chemical vapor deposition process was employed, argon and hydrogen were used as carrier gas, the flow rate of the carrier gas was 200 ml/min, ethane was used as carbon source, the heat treatment temperature was 900° C., and heat treatment was performed for 30 minutes, the growth temperature was 950° C., and the growth duration was 20 minutes. Graphene with high coverage, high quality and controllable layers continuously grew on the surface of the copper wire to obtain a graphene-coated copper wire with a controllable length (cf. FIG. 2).

(2) 3 samples were selected and twisted to obtain a twisted wire. The twisting degree was 15 T/cm. This operation was performed in air.

(3) The obtained twisted wire was heat-treated at 900° C. for 40 minutes to make the twisted wire become slack. The wire was stretched until it was straightened but withstood a tension of less than or equal to 1 N to achieve pre-tensioning, then was cooled to 180° C. for a mechanical pre-straining operation, and then was re-heated to 900° C. The above operations in step (3) were repeated 3 times, and finally an elongation of the twisted wire was 15%.

(4) The obtained samples were subjected to the same conditions and process as those in step (1), so that graphene grew on the surface thereof again.

(5) The obtained samples were subjected to cold drawing with a diamond high-precision drawing die at room temperature 15 times, and finally a graphene-copper composite wire with the same diameter as the initial copper wire was obtained.

(6) The obtained samples were subjected to the chemical vapor deposition process again, so that graphene grew on the surface thereof, wherein the process and conditions were the same as those in step (1).

Further, steps (2)-(6) may be repeated successively for the samples obtained in step (6), thereby realizing cyclic operations. Specifically, a copper wire with a diameter of 0.1 mm was subjected to step (1), then subjected to the above steps (2)-(6) and cycled 6 times, wherein 3 wires obtained in step (1) were selected for the first cycle, and 3 wires obtained in step (6) of previous cycle were selected for each of 5 subsequent cycles, thereby finally obtaining a graphene-copper composite wire with 3⁶ strands.

### Example 2

(1) A commercial copper wire with a diameter of 0.1 mm and a purity of 99% was washed with deionized water, ethanol, and acetone successively, and the washing was repeated 3 times. An atmospheric pressure chemical vapor deposition process was employed, argon and hydrogen were used as carrier gas, the flow rate of the carrier gas was 300 ml/min, ethane was used as carbon source, the heat treatment temperature was 900° C., the heat treatment was performed for 40 minutes, the growth temperature was 950° C., and the growth duration was 15 minutes. Graphene with high coverage, high quality and controllable layers continuously grew on the surface of the copper wire to obtain a copper wire fully coated with graphene and with a controllable length.

(2) 4 samples were selected and twisted to obtain a twisted wire. The twisting degree was 20 T/cm. This operation was performed in air (cf. FIG. 3).

(3) The obtained twisted wire was heat-treated at 900° C. for 40 minutes to make the twisted wire become slack. The wire was stretched until it was straightened but withstood a tension of less than or equal to 1 N to achieve pre-tensioning, then was cooled to 120° C. for a mechanical pre-straining operation, and then was re-heated to 900° C. The above operations in step (3) were repeated 3 times, and finally an elongation of the twisted wire was 15%.

(4) The obtained samples were subjected to the same conditions and process as those in step (1), so that graphene grew on the surface thereof again.

(5) The obtained samples were subjected to cold drawing with a diamond high-precision drawing die at room temperature 15 times, and finally a graphene-copper composite wire with the same diameter as the initial copper wire was obtained.

(6) The obtained samples were subjected to the chemical vapor deposition process again, so that graphene grew on the surface thereof, wherein the process and conditions were the same as those in step (1).

Further, steps (2)-(6) may be repeated successively for the samples obtained in step (6), thereby realizing cyclic operations. Specifically, a copper wire with a diameter of 0.1 mm was subjected to step (1), then subjected to the above steps (2)-(6) and cycled 6 times, wherein 4 wires obtained in step (1) were selected for the first cycle, and 4 wires obtained in step (6) of previous cycle were selected for each of 5 subsequent cycles, thereby finally obtaining a graphene-copper composite wire with 4⁶ strands.

### Example 3

(1) A commercial copper wire with a diameter of 0.2 mm and a purity of 99% was washed with deionized water, ethanol, and acetone successively, and the washing was repeated 3 times. An atmospheric pressure chemical vapor deposition process was employed, argon and hydrogen were used as carrier gas, the flow rate of the carrier gas was 250 ml/min, ethane was used as carbon source, the heat treatment temperature was 900° C., the heat treatment was performed for 60 minutes, the growth temperature was 950° C., and the growth duration was 10 minutes. Graphene with high coverage, high quality and controllable layers continuously grew on the surface of the copper wire to obtain a copper wire fully coated with graphene and with a controllable length.

(2) 3 samples were selected and twisted to obtain a twisted wire. The twisting degree was 20 T/cm. This operation was performed in air.

(3) The obtained twisted wire was heat-treated at 900° C. for 40 minutes to make the twisted wire become slack. The wire was stretched until the wire was straightened but withstood a tension of less than or equal to 1 N to achieve pre-tensioning, then was cooled to 150° C. for a mechanical pre-straining operation, and then was re-heated to 900° C. The above operations in step (3) were repeated 3 times, and finally an elongation of the twisted wire was 18%.

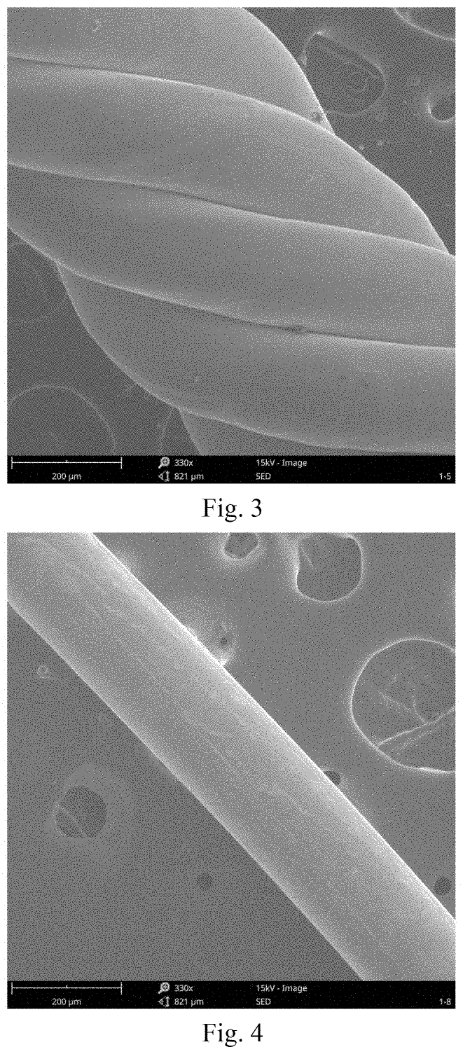

(4) The obtained samples were subjected to cold drawing with a diamond high-precision drawing die at room temperature 16 times, and finally a graphene-copper composite wire with the same diameter as the initial copper wire was obtained (cf. FIG. 4).

(5) The obtained samples were subjected to the chemical vapor deposition process again, so that graphene grew on the surface thereof, and the process and conditions were the same as those in step (1).

Further, steps (2)-(5) may be repeated successively for the samples obtained in step (5), thereby realizing cyclic operations. Specifically, a copper wire with a diameter of 0.2 mm was subjected to the above step (1), and then subjected to the above steps (2)-(5) and cycled 8 times, wherein 3 wires obtained in step (1) were selected for the first cycle, and 3 wires obtained in step (5) of previous cycle were selected for each of 7 subsequent cycles, thereby finally obtaining a graphene-copper composite wire with 3⁸ strands.

### Example 4

(1) A commercial copper wire with a diameter of 0.2 mm and a purity of 99% was washed with deionized water, ethanol, and acetone successively, and the washing was repeated 3 times. An atmospheric pressure chemical vapor deposition process was employed, argon and hydrogen were used as carrier gas, the flow rate of the carrier gas was 300 ml/min, methane was used as carbon source, the heat treatment temperature was 900° C., heat treatment was performed for 40 minutes, the growth temperature was 950° C., and the growth duration was 20 minutes. Graphene with high coverage, high quality and controllable layers continuously grew on the surface of the copper wire to obtain a copper wire fully coated with graphene and with a controllable length.

(2) 6 samples were selected and twisted to obtain a twisted wire. The twisting degree was 15 T/cm. This operation was performed in air.

(3) The obtained twisted wire was heat-treated at 800° C. for 40 minutes to make the twisted wire become slack. The wire was stretched until the wire was straightened but withstood a tension of less than or equal to 1 N to achieve pre-tensioning, then was cooled to 100° C. for a mechanical pre-straining operation, and then was re-heated to 800° C. The above operations in step (3) were repeated 3 times, and finally an elongation of the twisted wire was 18%.

(4) The obtained samples were subjected to the same conditions and process as those in step (1), and graphene grew on the surface thereof again.

(5) The obtained samples were subjected to cold drawing with a diamond high-precision drawing die at room temperature 15 times, and finally a graphene-copper composite wire with the same diameter as the initial copper wire was obtained.

(6) The obtained samples were subjected to the chemical vapor deposition process again, so that graphene grew on the surface thereof, wherein the process and conditions were the same as those in step (1).

Further, steps (2)-(6) may be repeated successively for the samples obtained in step (6), thereby realizing cyclic operations. Specifically, a copper wire with a diameter of 0.2 mm was subjected to step (1), and then subjected to the above steps (2)-(6) and cycled 8 times, where 6 wires obtained in step (1) were selected for the first cycle, and 6 wires obtained in step (6) of previous cycle were selected for each of 7 subsequent cycles, thereby finally obtaining a graphene-copper composite wire with 6⁸ strands.

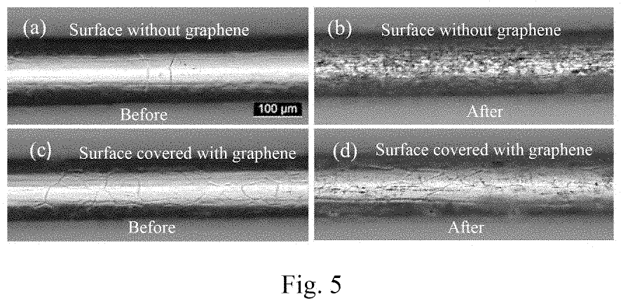

The graphene-copper composite wire has excellent oxidation resistance. In detail, after being heated to 200° C. for 5 minutes in an air environment, the graphene-copper composite wire was observed that only a small number of positions on the surface were oxidized, while blank control samples (i.e., copper wires without graphene) were completely oxidized on the surface (see FIG. 5 for comparison results).

### Example 5

(1) A commercial copper wire with a diameter of 0.3 mm and a purity of 99.9% was washed with deionized water, ethanol, and acetone successively, and the washing was repeated 3 times. An atmospheric pressure chemical vapor deposition process was employed, argon and hydrogen were used as carrier gas, the flow rate of the carrier gas was 300 ml/min, methane was used as carbon source, the heat treatment temperature was 900° C., the heat treatment was performed for 30 minutes, the growth temperature was 1000° C., and the growth duration was 20 minutes. Graphene with high coverage, high quality and controllable layers continuously grew on the surface of the copper wire to obtain a copper wire fully coated with graphene and with a controllable length.

(2) 4 samples were selected and twisted to obtain a twisted wire. The twisting degree was 20 T/cm. This operation was performed in air.

(3) The obtained twisted wire was heat-treated at 900° C. for 40 minutes to make the twisted wire become slack. The wire was stretched until the wire was straightened but withstood a tension of less than or equal to 1 N to achieve pre-tensioning, then was cooled to 150° C. for a mechanical pre-straining operation, and then was re-heated to 900° C. The above operations in step (3) were repeated 3 times, and finally an elongation of the twisted wire was 18%.

(4) The obtained samples were subjected to the same conditions and process as those in step (1), and graphene grew on the surface thereof again.

(5) The samples obtained in step (4) were subjected to cold drawing with a diamond high-precision drawing die at room temperature 15 times, and finally a graphene-copper composite wire with the same diameter as the initial copper wire was obtained.

(6) The obtained samples were subjected to the chemical vapor deposition process again, so that graphene grew on the surface thereof, wherein the process and conditions were the same as those in step (1).

Further, steps (2)-(6) may be repeated successively for the samples obtained in step (6), thereby realizing cyclic operations. Specifically, a copper wire with a diameter of 0.3 mm was subjected to step (1), and then subjected to the above steps (2)-(6) and cycled 6 times, wherein 4 wires obtained in step (1) were selected for the first cycle, and 4 wires obtained in step (6) of previous cycle were selected for each of 5 subsequent cycles, thereby finally obtaining a graphene-copper composite wire with 4⁶ strands.

### Example 6

(1) A commercial copper wire with a diameter of 0.3 mm and a purity of 99.9% was washed with deionized water, ethanol, and acetone successively, and the washing was repeated 3 times. An atmospheric pressure chemical vapor deposition process was employed, argon and hydrogen were used as carrier gas, the flow rate of the carrier gas was 350 ml/min, methane was used as carbon source, the heat treatment temperature was 900° C., the heat treatment was performed for 40 minutes, the growth temperature was 1050° C., and the growth duration was 10 minutes. Graphene with high coverage, high quality and controllable layers continuously grew on the surface of the copper wire to obtain a copper wire fully coated with graphene and with a controllable length.

(2) 8 samples were selected and twisted to obtain a twisted wire. The twisting degree was 16 T/cm. This operation was performed in argon.

(3) The obtained twisted wire was heat-treated at 1000° C. for 40 minutes to make the twisted wire become slack. The wire was stretched until the wire was straightened but withstood a tension of less than or equal to 1 N to achieve pre-tensioning, then was cooled to 150° C. for a mechanical pre-straining operation, and then was re-heated to 1000° C. The above operations in step (3) were repeated 5 times, and finally an elongation of the twisted wire was 20%.

(4) The obtained samples were subjected to the same conditions and process as those in step (1), and graphene grew on the surface thereof again.

(5) The obtained samples were subjected to cold drawing with a diamond high-precision drawing die at room temperature 20 times, and finally a graphene-copper composite wire with the same diameter as the initial copper wire was obtained.

(6) The obtained samples were subjected to the chemical vapor deposition process again, so that graphene grew on the surface thereof, wherein the process and conditions were the same as those in step (1).

Further, steps (2)-(6) may be repeated successively for the samples obtained in step (6), thereby realizing cyclic operations. Specifically, a copper wire with a diameter of 0.3 mm was subjected to step (1), and then subjected to the above steps (2)-(6) and cycled 6 times, where 8 wires obtained in step (1) were selected for the first cycle, and 8 wires obtained in step (6) of previous cycle were selected for each of 5 subsequent cycles, thereby finally obtaining a graphene-copper composite wire with 8⁶ strands.

### Example 7

(1) A commercial copper wire with a diameter of 0.5 mm and a purity of 99.9% was washed with deionized water, ethanol, and acetone successively, and the washing was repeated 3 times. An atmospheric pressure chemical vapor deposition process was employed, argon and hydrogen were used as carrier gas, the flow rate of the carrier gas was 300 ml/min, ethylene was used as carbon source, the heat treatment temperature was 900° C., heat treatment was performed for 35 minutes, the growth temperature was 1000° C., and the growth duration was 15 minutes. Graphene with high coverage, high quality and controllable layers continuously grew on the surface of the copper wire to obtain a copper wire fully coated with graphene and with a controllable length.

(2) 4 samples were selected and twisted to obtain a twisted wire. The twisting degree was 20 T/cm. This operation was performed in argon.

(3) The obtained twisted wire was heat-treated at 1050° C. for 40 minutes to make the twisted wire become slack. The wire was stretched until the wire was straightened but withstood a tension of less than or equal to 1 N to achieve pre-tensioning, then was cooled to 160° C. for a mechanical pre-straining operation, and then was re-heated to 1050° C. The above operations in step (3) were repeated 3 times, and finally an elongation of the twisted wire was 18%.

(4) The obtained samples were subjected to the same conditions and process as those in step (1), and graphene grew on the surface thereof again.

(5) The obtained samples were subjected to cold drawing with a diamond high-precision drawing die at room temperature 20 times, and finally a graphene-copper composite wire with the same diameter as the initial copper wire was obtained.

(6) The obtained samples were subjected to the chemical vapor deposition process again, so that graphene grew on the surface thereof, and the process and conditions were the same as those in step (1).

Further, steps (2)-(6) may be repeated successively for the samples obtained in step (6), thereby realizing cyclic operations. Specifically, a copper wire with a diameter of 0.5 mm was subjected to step (1), and then subjected to the above steps (2)-(6) and cycled 6 times, where 4 wires obtained in step (1) were selected for the first cycle, and 4 wires obtained in step (6) of previous cycle were selected for each of 5 subsequent cycles, thereby finally obtaining a graphene-copper composite wire with 4⁶ strands.

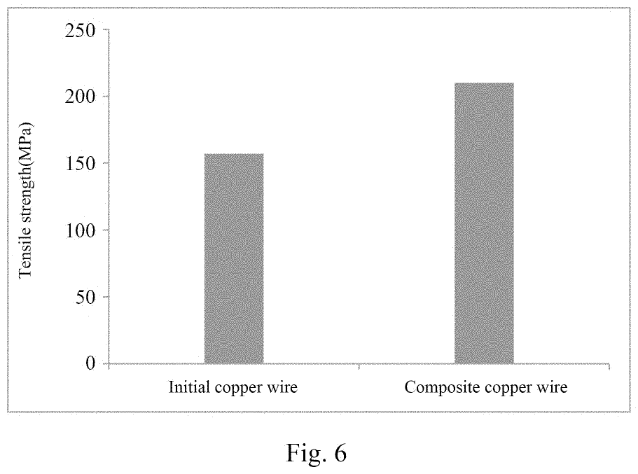

The composite copper wire was tested for tensile performance with an electronic universal tensile tester, and its tensile strength was improved to greater than 200 MPa, as shown in FIG. 6.

Those skilled in the art can understand that appropriate modification and changes may be made to the embodiments of the present disclosure, without departing from the spirit or scope of the present disclosure. The scope of the present disclosure is intended to be determined by the appended claims and equivalents thereof.

1. A method for manufacturing a graphene-metal composite wire, comprising the steps of:
(1) growing graphene on a surface of a metal wire through a chemical vapor deposition process;
(2) twisting the wire;
(3) heat-treating the wire at 600-1100° C. for 30-60 minutes so that the wire becomes slack, then subjecting the wire to a pre-tensioning operation immediately after the heat treatment, and then cooling the wire to below 200° C. for a pre-straining operation;
(4) cold-drawing the wire to obtain a densified structure; and
(5) subjecting the wire to a chemical vapor deposition process,
wherein the wire is subjected to steps (2) to (5) successively and cycled n times, wherein f wires obtained in step (1) are used in the first cycle, f wires obtained from previous cycle are used in subsequent cycle, and finally a graphene-metal composite wire with fⁿ strands is obtained, and wherein (a) f is an integer of 2-9;
and (b) n is an integer of 6 or more.

2. (canceled)

3. The method according to claim 1, wherein the method comprises an optional step (3′) between step (3) and step (4): subjecting the wire to a chemical vapor deposition process so that graphene grows on the surface thereof.

4. The method according to claim 1, wherein the chemical vapor deposition process in step (1) is an atmospheric pressure chemical vapor deposition process or a low-pressure chemical vapor deposition process at a pressure of 1-300 Pa, in which a carrier gas is selected from the group consisting of argon, helium, hydrogen, and any combination thereof; a carbon source is a gaseous carbon source or a liquid carbon source, the gaseous carbon source is selected from the group consisting of methane, ethane, ethylene, and any combination thereof, and the liquid carbon source is selected from the group consisting of methanol, ethanol, methylbenzene, and any combination thereof.

5. The method according to claim 1, wherein the chemical vapor deposition process in step (1) comprises heat-treating the metal wire by heating the metal wire to a temperature of 800-1100° C. and maintaining for 30-100 minutes;
heating the metal wire to a growth temperature that is in a range of 800-1100° C. and equal to or higher than the heat treatment temperature, and contacting the metal wire with a carrier gas carrying a carbon source, so that graphene grows on the surface of the metal wire for 5-60 minutes, wherein the carrier gas has a flow rate of 1-500 ml/min.

6. The method according to claim 1, wherein the chemical vapor deposition process used in step (5) and the chemical vapor deposition process used in the optional step (3′) are the same as the chemical vapor deposition process in step (1).

7. The method according to claim 1, wherein the twisting in step (2) is carried out in an atmosphere of air, argon or helium, and a twisting degree is 5-40 T/cm.

8. The method according to claim 1, wherein step (3) comprises heat-treating the wire at 600-1100° C. for 30-60 minutes so that the wire becomes slack; subjecting the wire to a pre-tensioning operation immediately after the heat treatment, then cooling the wire to below 200° C. for a pre-straining operation; and repeating step (3) 3-8 times in a single cycle so that an elongation of the wire is 10-30%.

9. The method according to claim 2, wherein step (4) comprises subjecting the wire obtained in step (3) or (3′) to cold drawing with a cold drawing die at atmospheric pressure and room temperature 1-30 times, wherein the wire is elongated by 2-5% during each cold drawing, and a diameter of the wire finally obtained in step (4) is the same as initial diameter of the metal wire in step (1).

10. The method according to claim 1, wherein the metal wire is a copper wire or a nickel wire.

11. The method according to claim 9, wherein the metal wire is a red copper wire with a purity of 95-99.999% and a diameter of 0.05-0.5 mm.

12. The method according to claim 9, wherein the metal wire is a commercial copper, and the metal wire is washed before step (1), wherein the washing includes washing the metal wire with one or more solvents selected from the group consisting of deionized water, ethanol, acetone, isopropanol, and trichloromethane, and repeating the washing 2-3 times.
